(19) United States
(12) Patent Application Publication
(10) Pub. No.: US 2003/0092278 A1
(43) Pub. Date: May 15, 2003

(54) Plasma baffle assembly

(76) Inventor: Steven T. Fink, Mesa, AZ (US)

Correspondence Address: PILLSBURY WINTHROP, LLP, P.O. BOX 10500, MCLEAN, VA, 22102, US

(21) Appl. No.: 10/291,533

(22) Filed: Nov. 12, 2002

Related U.S. Application Data
(60) Provisional application No. 60/331,253, filed on Nov. 13, 2001.

(51) Int. Cl. H01L 21/461; H01L 21/302

(52) U.S. Cl. 438/710; 438/709

(57) ABSTRACT

A plasma processing apparatus and a method for improving plasma characteristics by controlling the dissociation and ionization in the plasma are described. The method includes providing a flow of precursor gas into a process chamber, and evacuating excess gas from process chamber, disposing a substrate material on a substrate holder in the process chamber, forming a plasma from the precursor gas in a plasma volume within the process chamber and attenuating the plasma in a space surrounding the substrate with a baffle assembly and the substrate holder. The walls of the baffle assembly surround the outside edges and a portion of a surface of the substrate holder opposed to a surface on which the substrate is disposed.

This application is based on and derives the benefit of U.S. Provisional Application No. 60/331,253 filed Nov. 13, 2001, the contents of which are incorporated herein in their entirety by reference.

### BACKGROUND

1. Field of Invention

The invention relates to plasma processing apparatus, and more particularly, to plasma processing apparatus including a baffle assembly.

2. Discussion of Related Art

Plasma processing systems are used in the manufacture and processing of semiconductors, integrated circuits, displays and other devices or materials, to both remove material from or to deposit material on a substrate such as a semiconductor substrate. In plasma processing systems, one factor affecting the degree of etch or deposition uniformity is the spatial uniformity of the plasma density above the substrate.

In the prior art, plasma has been attenuated in the process chamber with various baffle plates. One function of the attenuation has been to improve the confinement of the plasma in the process chamber. Another function of these plates has been to keep plasma from entering areas where harm could occur to mechanical components. One area that is regularly protected is the Turbo Molecular Pump (TMP). A flat plate with many small-diameter holes of high aspect ratio separate the process chamber with its associated plasma from the TMP, thus protecting the TMP. These plates are of various configurations, most cover the pumping port. Another function of baffle plates has been to regulate the flow of gases in the process chamber and also to adjust the flow of gases entering a pumping port in cases where the chamber is pumped in a non-uniform manner.

### SUMMARY OF THE INVENTION

This invention pertains to plasma processing apparatus and a method for improving plasma characteristics by controlling the dissociation and ionization in the plasma. The plasma processing apparatus and method employs a plasma baffle assembly for attenuating the plasma in a space surrounding the substrate.

### BRIEF DESCRIPTION OF THE DRAWINGS

FIG. 1 is a schematic representation of a plasma processing apparatus showing a configuration of the plasma baffle according to one embodiment of the present invention;

FIGS. 2A-2B show an example of hole configuration with various hole shapes, in one embodiment of the plasma baffle;

FIG. 3 shows an enlarged cut-away view of plasma baffle assembly according to one embodiment of the present invention; and

FIGS. 4A-4C show alternative shapes for the plasma baffle according to alternative embodiments of the present invention.

### DETAILED DESCRIPTION OF THE PREFFERED EMBODIMENTS

In the following description, in order to facilitate a thorough understanding of the invention and for purposes of explanation and not limitation, specific details are set forth such as a particular geometry of the process chamber and/or the plasma baffle assembly and use of gases, radio-frequency generating techniques, etc. However, the invention may be practiced in other embodiments that depart from these specific details. The term plasma is used in its broadest definition as being a relatively hot mixture of electrons, negative and positive ions as well as neutral species such as atoms, molecules and radicals.

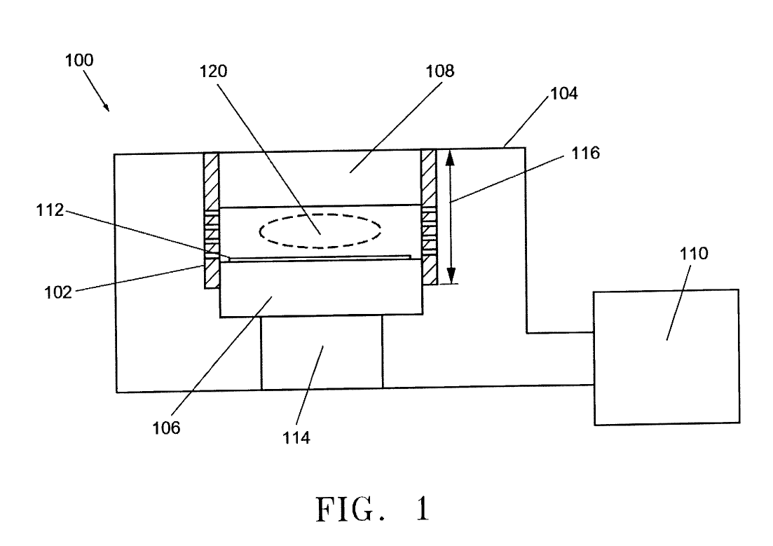

FIG. 1 is a schematic representation of a plasma processing apparatus 100 showing a configuration of a plasma baffle 102 according to one embodiment of the present invention. In the following description those elements of the plasma processing apparatus 100 necessary to illustrate the present invention will be put forward, however, it should be understood that other elements are also present.

The processing apparatus of the present invention further comprises process chamber 104, substrate holder 106 also playing the role of bias electrode, plasma generating electrode 108, and vacuum pump 110. Substrate 112 is placed on the surface of substrate holder 106 facing electrode 108. In one embodiment, plasma baffle assembly 102 surrounds the outside edges of substrate holder 106. The plasma baffle assembly 102 is constructed from a material such as quartz or ceramic material. This baffle assembly 102 may be formed to conform for example to the lower portions of the plasma generating electrode assembly 108 while extending down, cylindrically, to closely surround the plasma proximate to substrate 112. In one embodiment, the baffle assembly encloses the substrate holder 106 during processing and permits substrate 112 exchange when the substrate holder 106 is lowered to a transfer position by translation device 114.

The cylindrical baffle wall 102, that extends between the plasma generating electrode 108 and the bias electrode 106, is perforated by many high aspect ratio holes, not shown on this figure, of various diameters. High aspect ratio holes are holes having their depth greater than their width. In one embodiment, this cylindrical section is long enough to enclose the chuck assembly or substrate holder 106 during process but not long enough to hamper substrate 112 exchange when the substrate holder 106 is in its lowest or transfer position. In another embodiment, the cylindrical baffle wall 102 extends to a length 116 enough to control the plasma proximate the substrate 112. The length 116 of cylindrical baffle 102 is tailored depending on various parameters such as, but not limited to, the diameter of substrate 112 and the plasma process utilized. In one embodiment, the diameter of the cylindrical baffle 102 is between approximately 200 mm and 500 mm and the length 116 between 5 mm and 60 mm or more depending on plasma conditions.

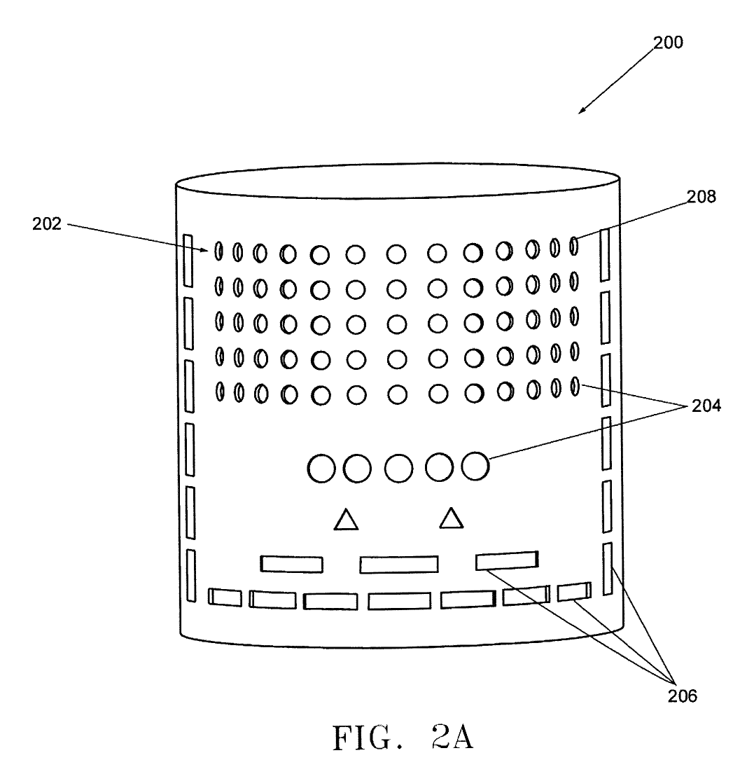

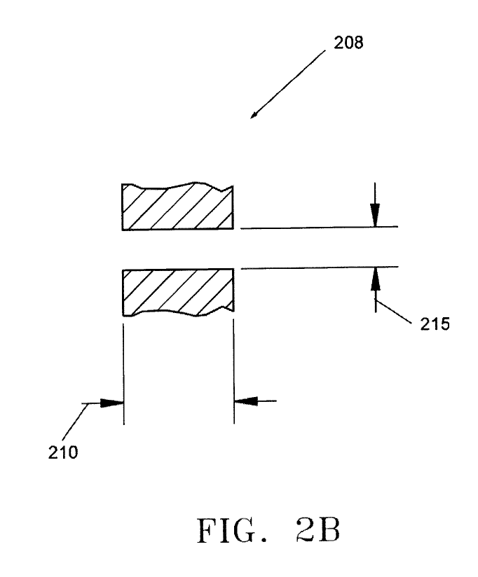

In one embodiment, the high aspect ratio holes substantially attenuate the plasma 120 in an area bounded by the substrate holder 106, the upper electrode 108 and the baffle cylinder 102. Gases are exhausted through the holes to the pumping system 110. As shown in FIG. 2A, in one embodiment of the plasma baffle 200, the holes 202 can be designed of various shapes and sizes over the surface of the cylindrical baffle to control the gas flow and to control the density of the plasma 120. For example, holes 204 or other features such as slots 206 may be positioned to selectively let plasma “leak” from the containment area, thus affecting uniformity or plasma density in local areas where desired. FIG. 2B shows an enlargement of the cross-section view of an example of high aspect ratio hole 208 with its depth 210 greater than its width 215. In one embodiment of the plasma baffle 200, instead of using holes, the material forming the walls of the plasma baffle is a porous ceramic material.

In another embodiment, the baffle cylinder 102 is constructed of a wire-grid, the wire being an electric conductor such as, but not limited to, aluminum or copper. The cylindrical wire-grid is arranged away from lower electrode 106 such as to avoid a potential electric discharge between the grid and the lower electrode. In a further embodiment, the cylindrical wire-grid baffle is biased with a DC voltage to provide additional control of the charged species present in the plasma in the vicinity of substrate 112. In another embodiment, the cylindrical wire-grid can be replaced by an electric conducting cylinder comprising holes having various shapes and designs. Similarly to the wire-grid, the electric conducting cylinder can be biased with a voltage to provide additional control of the plasma shape and density.

In another embodiment the electric conducting cylinder comprising holes having various shapes and designs, whether electrically biased with voltage, grounded or at a floating potential, can be coated with a protective barrier. For example, the protective barrier can comprise a compound including an oxide of aluminum such as Al₂O₃. Alternately, the protective barrier can comprise a mixture of Al₂O₃ and Y₂O₃. In another embodiment of the present invention, the protective barrier can comprise at least one of a III-column element (column III of periodic table) and a Lanthanon element. In another embodiment of the present invention, the III-column element can comprise at least one of Yttrium, Scandium, and Lanthanum. In another embodiment of the present invention, the Lanthanon element can comprise at least one of Cerium, Dysprosium, and Europium. In another embodiment of the present invention, the compound forming protective barrier 150 can comprise at least one of Yttria (Y₂O₃), Sc₂O₃, Sc₂F₃, YF₃, La₂O₃, CeO₂, Eu₂O₃, and DyO₃.

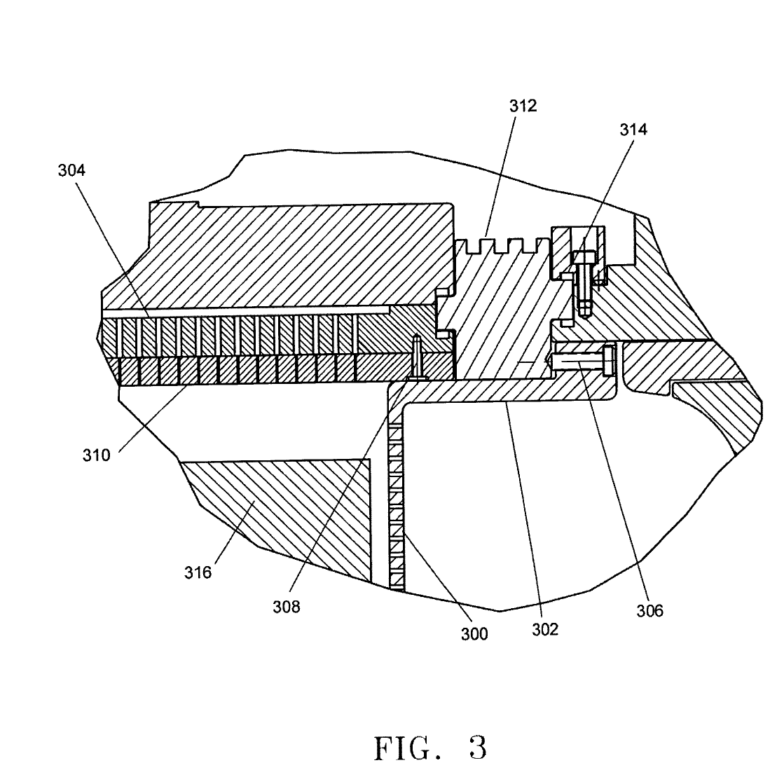

In one embodiment, illustrated in FIG. 3, the plasma baffle assembly 300 as depicted comprises a shield ring portion 302 and can be attached to the plasma processing system in the same manner as an existing shield ring component. For example, the shield ring portion can be attached to the plasma processing system with set-screws 306. The shield ring portion 302 can be used to shield inserts 308 holding silicon plate 310 to electrode 304. Insulator 312 is used to isolate shield ring 306 and therefore baffle assembly 300 from electrode 304. Insulator 312 is held to the electrode 304 with fasteners 314. Plasma baffle 300 is arranged away from lower electrode/substrate holder 316. Accessibility for maintenance is made simple by incorporating both pieces of hardware into one single piece thus eliminating additional work involved in servicing.

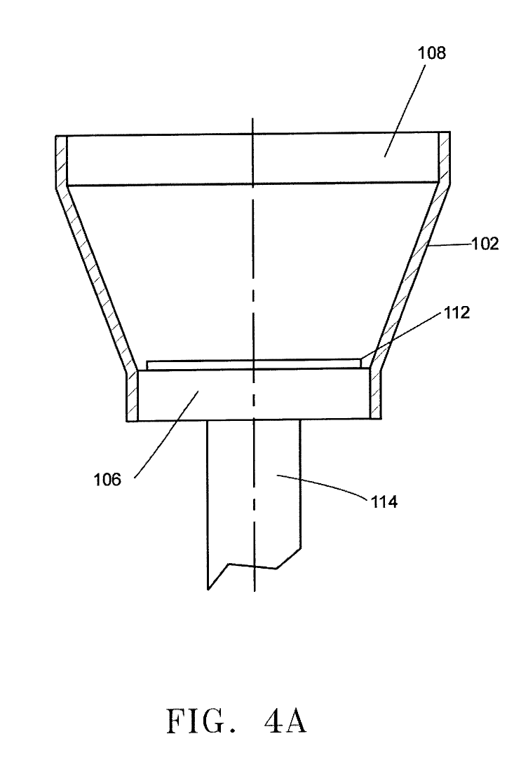

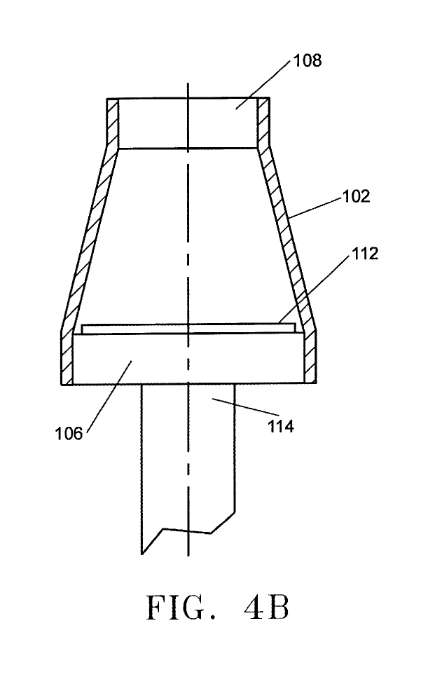

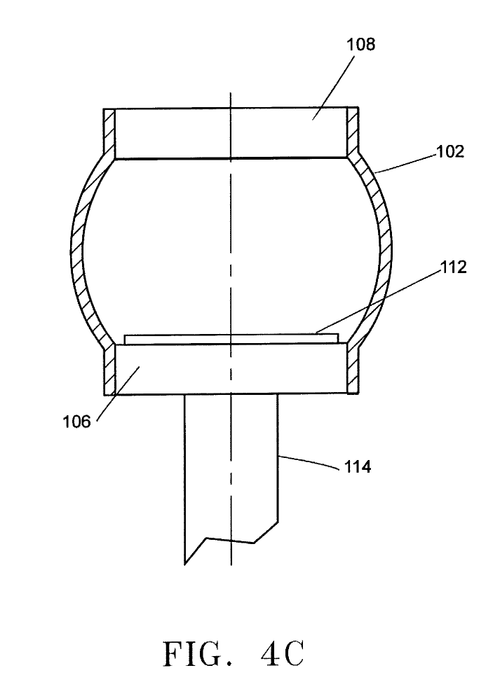

Instead of a cylindrical section, other shapes could be used as plasma baffle 102. Alternative embodiments include, for example, shapes such as a conical section, a polygonal section and spherical section. FIGS. 4A-4C show examples of embodiments for the plasma baffle assembly. FIG. 4A shows a baffle assembly having a conical shape having a larger section at the top than the bottom. FIG. 4B shows a reverse configuration where the conical shape is larger at the bottom that the top. FIG. 4C shows a baffle assembly having a spherical section. The baffle assembly can also have polygonal sections instead of a rounded section as in cylindrical, conical or spherical sections. Use of a combination of shapes is also possible, such as but not limited to, a cylindrical-spherical shape or a conical-spherical shape.

Although the baffle assembly 102 is illustrated on FIGS. 4A, 4B and 4C as enclosing substrate 112, it is however understood that this is only one possible embodiment and other possible embodiments can be for example the wall of baffle assembly 102 not extending to fully enclose the substrate. Indeed, as previously mentioned the length of plasma baffle assembly can be tailored for a specific plasma process.

While a detailed description of presently preferred embodiments of the invention have been given above, various alternatives, modifications, and equivalents will be apparent to those skilled in the art without varying from the spirit of the invention. Therefore, the above description should not be taken as limiting the scope of the invention, which is defined by the appended claims.

What is claimed is:

1. A method for attenuating a plasma around a process region, the method comprising:
disposing a substrate material on a substrate holder in the process chamber;
providing a flow of precursor gas into the process chamber;
evacuating excess gas from the process chamber;
forming a plasma from said precursor gas in a plasma volume within the process chamber; and
attenuating said plasma in a space proximate the substrate with a baffle assembly.

2. The method for attenuating a plasma around process region as recited in claim 1, further comprising surrounding the space proximate the substrate with a cylindrically shaped baffle assembly.

3. The method for attenuating a plasma around a process region as recited in claim 1, further comprising surrounding the space proximate the substrate with an inner wall of a conically shaped baffle assembly, wherein a smaller annular section of the conical shape is oriented towards the substrate holder.

4. The method for attenuating a plasma around a process region as recited in claim 1, further comprising surrounding the space proximate the substrate with an inner wall of a spherically shaped baffle assembly.

5. The method for attenuating a plasma around a process region as recited in claim 1, further comprising surrounding the space proximate the substrate with an inner wall of a conically shaped baffle assembly, wherein a larger annular section of the conical shape is oriented towards the substrate holder.

6. The method for attenuating a plasma around a process region as recited in claim 1, further comprising surrounding the space proximate the substrate with lateral polygonal faces of a polygonal baffle assembly.

7. The method for attenuating a plasma around a process region as recited in claim 1, further comprising surrounding the space proximate the substrate with said baffle assembly, wherein said baffle assembly comprises a combination of shapes selected from the group consisting of cylindrical, conical, polygonal, and spherical shapes.

8. The method for attenuating a plasma around a process region as recited in claim 1, further comprising positioning said baffle assembly between a bias electrode and a plasma generating electrode wherein the bias electrode comprises the substrate holder and the plasma generating electrode supports the baffle assembly.

9. The method for attenuating a plasma around a process region as recited in claim 1, further comprising enclosing the substrate holder with said baffle assembly during a process and permitting substrate exchange when the substrate holder is lowered to a transfer position.

10. The method for attenuating a plasma around a process region as recited in claim 9, wherein said plasma is attenuated in an area bounded by the lower electrode, the upper electrode and the walls of said baffle assembly.

11. The method for attenuating a plasma around a process region as recited in claim 1, wherein said baffle assembly is perforated by high aspect ratio holes.

12. The method for attenuating a plasma around a process region as recited in claim 11, further comprising exhausting excess gas through the holes in the baffle assembly to a pumping system attached to the process chamber.

13. The method for attenuating a plasma around a process region as recited in claim 1, further comprising controlling the uniformity of the plasma density in areas where desired by positioning features comprising holes of various shapes and dimensions in the baffle assembly.

14. The method for attenuating a plasma around a process region as recited in claim 1, further comprising controlling the uniformity of the plasma density in areas where desired by adjusting the length of said baffle assembly.

15. The method for attenuating a plasma around a process region as recited in claim 1, further comprising controlling the uniformity of the plasma density in areas where desired by adjusting the diameter of said baffle assembly.

16. The method for attenuating a plasma around a process region as recited in claim 1, further comprising controlling the uniformity of the plasma density in areas where desired by adjusting the position of said baffle assembly.

17. The method for attenuating a plasma around a process region as recited in claim 1, wherein said baffle assembly is perforated with slots positioned to control said plasma.

18. The method for attenuating a plasma around a process region as recited in claim 1, wherein said baffle assembly is constructed from a material selected from the group comprising quartz and ceramics.

19. The method for attenuating a plasma around a process region as recited in claim 18, wherein said ceramics consist of porous ceramics.

20. The method for attenuating a plasma around a process region as recited in claim 1, wherein said baffle assembly is constructed from an electrically conductive material.

21. The method for attenuating a plasma around a process region as recited in claim 20, wherein said baffle assembly is coated with a protective barrier.

22. The method for attenuating a plasma around a process region as recited in claim 20, wherein said baffle assembly consists of wire-grid.

23. The method for attenuating a plasma around a process region as recited in claim 20, wherein said baffle assembly is biased with voltage.

24. The method for attenuating a plasma around a process region as recited in claim 1, wherein the substrate holder is slidable between positions respectively inside and outside the baffle assembly.

25. The method for attenuating a plasma around a process region as recited in claim 1, wherein the baffle assembly further comprises a shield ring component.

26. A plasma process apparatus with baffle assembly comprising:
a process chamber;
a plasma generating system configured and arranged to produce a plasma in the process chamber;
a gas source configured to introduce gases into the process chamber;
a pressure-control system to maintain a selected pressure within the process chamber;
a substrate holder configured to hold a substrate during substrate processing; and
a baffle assembly disposed radially outward of said substrate to attenuate said plasma proximate to said substrate.

27. The plasma process apparatus with baffle assembly as recited in claim 26, wherein said baffle assembly is a shape selected from the group consisting of a cylindrical form, a conical form, a polygonal form and a spherical form.

28. The plasma process apparatus with baffle assembly as recited in claim 26, wherein said baffle assembly comprises high aspect ratio holes perforated on a wall of said baffle assembly.

29. The plasma process apparatus with baffle assembly as recited in claim 26, wherein said baffle assembly comprises slots perforated on a wall of said baffle assembly.

30. The plasma process apparatus with baffle assembly as recited in claim 26, wherein said baffle assembly is constructed from a material selected from the group consisting of quartz and ceramics.

31. The plasma process apparatus with baffle assembly as recited in claim 26, wherein said baffle assembly is constructed from an electric conductive material.

32. The plasma process apparatus with baffle assembly as recited in claim 31 wherein said baffle assembly is coated with a protective barrier.

33. The plasma process apparatus with baffle assembly as recited in claim 31, wherein said baffle assembly is constructed from an electric conducting wire-grid.

34. The plasma process apparatus with baffle assembly as recited in claim 31, wherein said baffle assembly is biased with voltage.

35. The plasma process apparatus with baffle assembly as recited in claim 26, wherein said substrate holder is slidable between positions respectively inside and outside said baffle assembly.
